(19) United States
(12) Patent Application Publication
(10) Pub. No.: US 2009/0039450 A1
(43) Pub. Date: Feb. 12, 2009

(54) STRUCTURE OF MAGNETIC MEMORY CELL AND MAGNETIC MEMORY DEVICE

(75) Inventors: Yuan-Jen Lee, Taipei County (TW); Ding-Yeong Wang, Hsinchu County (TW); Chien-Chung Hung, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 11/964,008

(22) Filed: Dec. 25, 2007

(30) Foreign Application Priority Data
Aug. 9, 2007 (TW) 96129379

(51) Int. Cl. H01L 29/82

(52) U.S. Cl. 257/421; 257/E29.323

(57) ABSTRACT

A structure of magnetic memory cell including a first anti-ferromagnetic layer is provided. A first pinned layer is formed over the first anti-ferromagnetic layer. A tunneling barrier layer is formed over the first pinned layer. A free layer is formed over the tunneling barrier layer. A metal layer is formed over the free layer. A second pinned layer is formed over the metal layer. A second anti-ferromagnetic layer is formed over the second pinned layer.

### CROSS-REFERENCE TO RELATED APPLICATION

This application claims the priority benefit of Taiwan application serial no. 96129379, filed on Aug. 9, 2007. The entirety of the above-mentioned patent application is hereby incorporated by reference herein and made a part of this specification.

### BACKGROUND OF THE INVENTION

1. Field of the Invention

The present invention relates to a structure of memory cell. More particularly, the present invention relates to a structure of magnetic memory cell.

2. Description of Related Art

Magnetic memory, for example magnetic random access memory (MRAM), is also a non-volatile memory, and has advantages such as non-volatility, high density, high read and write speed, and radiation hardness. Data of logic “0” or logic “1” is recorded by the magnitude of magnetoresistance generated by the parallel or the anti-parallel arrangement of magnetic moments of magnetic substance neighboring a tunneling barrier layer. When writing the data, two current lines, for example a write bit line (WBL) and a write work line (WWL), are usually used to sense the magnetic memory cell selected by the intersection of the magnetic field, and the magnetoresistance value thereof is altered by changing the direction of the magnetization of a free layer. When reading the memory data, current flows into the selected magnetic memory cell, so as to determine the digital value of the memory data according to the read resistance value.

FIG. 1 is a basic structure of a magnetic memory cell. Referring to FIG. 1, in order to access and write a magnetic memory cell, current lines 100 and 102, which are crossed and have suitable current, are required. According to the operation manner, they are also referred to as, for example, a bit line and a word line. When the current flows into the two leads, magnetic fields with two directions are generated, thereby obtaining the required magnetic field magnitude and direction, so as to apply on a magnetic memory cell 104. The magnetic memory cell 104 is a laminated structure, which includes a magnetic pinned layer having a fixed magnetization or a total magnetic moment on a predetermined direction. An angle difference of the magnetization between a magnetic free layer and the magnetic pinned layer is used to generate different magnetoresistance magnitudes to read the data. Also, if it intends to write the data, it is also possible to apply a writing magnetic field, so as to determine the magnetization direction of the magnetic free layer. Output electrodes 106 and 108 are used to read the data stored in the memory cell. Those of ordinary skill in the art can understand the operation details of the magnetic memory, so it is not described.

FIG. 2 is a memory mechanism of the magnetic memory. Referring to FIG. 2, a magnetic pinned layer 104a has a fixed magnetic moment direction 107. A magnetic free layer 104c is located above the magnetic pinned layer 104a, and a tunnel barrier layer 104b is disposed there-between to isolate the magnetic free layer 104c and the magnetic pinned layer 104a. The magnetic free layer 104c has a magnetic moment direction 108a or 108b. The magnetic moment direction 107 is parallel to the magnetic moment direction 108a, so the generated magnetoresistance indicates, for example, the data of “0”. On the contrary, the magnetic moment direction 107 is anti-parallel to the magnetic moment direction 108b, so the generated magnetoresistance indicates, for example, the data of “1”.

The magnetic free layer 104c of FIG. 2 is a single layer structure, so data error is likely generated in operation. In U.S. Pat. No. 6,545,906, for the free layer, a ferromagnetic/non-magnetic metal/ferromagnetic three-layer structure is used to replace the single layer ferromagnetic material, so as to reduce the interference situation of the neighboring cells when writing the data. FIG. 3 shows a structure of magnetic memory cell, which includes a pinned layer 120, a tunneling layer 128, and a magnetic free layer 130. The pinned lamination layer 120 is composed of a bottom pinned layer 122, a magnetic coupling spacer 124, and a top pinned layer 126. The magnetic free lamination layer 130 is composed of a bottom ferromagnetic layer 132, a non-magnetic metal layer 134, and a top ferromagnetic layer 136. Arrows in the drawing indicate the directions of the magnetization. The magnetizations of the bottom ferromagnetic layer 132 and the top ferromagnetic layer 136 are disposed in anti-parallel, and can be changed by the externally applied operation magnetic field, so as to change the stored data. The data depend on the magnetoresistance change caused by the magnetization between the top pinned layer 126 and the bottom ferromagnetic layer 132.

In order to reduce the interference situation of the neighboring cells when writing the data, for the free layer, the ferromagnetic/non-magnetic metal/ferromagnetic three-layer structure is used to replace the single layer ferromagnetic material, and the two ferromagnetic layers above and below the non-magnetic metal are arranged in anti-parallel. In addition, in order to match with a toggle operation mode, the provided current is written in a certain sequence, and an angle between the WBL and the WWL and the magnetic easy axis of the free layer is 45 degrees.

The above method is the so-called toggle operation mode, so as to reduce the interference problem. However, the current required to switch the free layer of three-layer structure becomes larger. In order to lower the write current, on the basis of the toggle operation mode, a bias field is also added in the conventional art. FIG. 4 is a schematic view of the mechanism of reducing the write current in the conventional art. Referring to FIG. 4, for example, the word line generates a magnetic field H_{W} in an X axis direction, and the bit line generates a magnetic field H_{B} in a Y axis direction. A first quadrant region 140 is a toggle operation region, and a region 142 is a non-operation region. A fringe field of the pinned layer is used to generate a bias field 144 on the free layer, so as to move the region 140 towards the origin to reduce the magnitude of the operation magnetic field, that is, to reduce the operation current.

However, the above mechanism of reduce the operation current by using the bias field still has limitations. It is still a topic to be continuously researched and developed how to achieve the operation of substantially further lowering the write current matching with the structure of magnetic memory cell.

### SUMMARY OF THE INVENTION

One exemplary of the present invention provides a structure of magnetic memory cell, which includes a first anti-ferromagnetic (AFM) layer. A first pinned layer is formed over the first anti-ferromagnetic layer. A tunneling barrier layer is formed over the first pinned layer. A free layer is formed over the tunneling barrier layer. A metal layer is formed over the free layer. A second pinned layer is formed over the metal layer. A second anti-ferromagnetic layer is formed over the second pinned layer.

The present invention also provides a magnetic memory device, which includes a plurality of abovementioned magnetic memory cells disposed in an array.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a basic structure of a magnetic memory cell.

FIG. 2 is a memory mechanism of the magnetic memory.

FIG. 3 shows a structure of magnetic memory cell including a pinned lamination layer, a tunneling layer, and a magnetic free lamination layer.

FIG. 4 is a schematic view of the mechanism of reducing the write current in the conventional art.

FIG. 5 is a schematic view of the conventional mechanism of applying the bias field and the problem discussion according to the present invention.

FIG. 6 is a schematic view of the effect of conventionally applying the bias field according to the present invention.

FIG. 7 is a schematic view of discussing the mechanism of the bias field resulting in the operation failure according to the present invention.

FIG. 8 is a schematic sectional view of the structure of magnetic memory cell according to an embodiment of the present invention.

FIGS. 9-10 are schematic views of the structure and the simulated result according to an embodiment of the present invention.

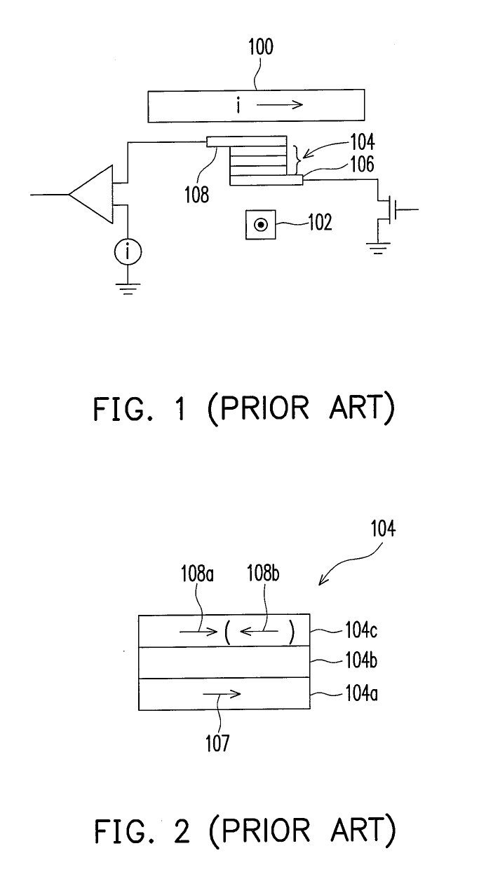

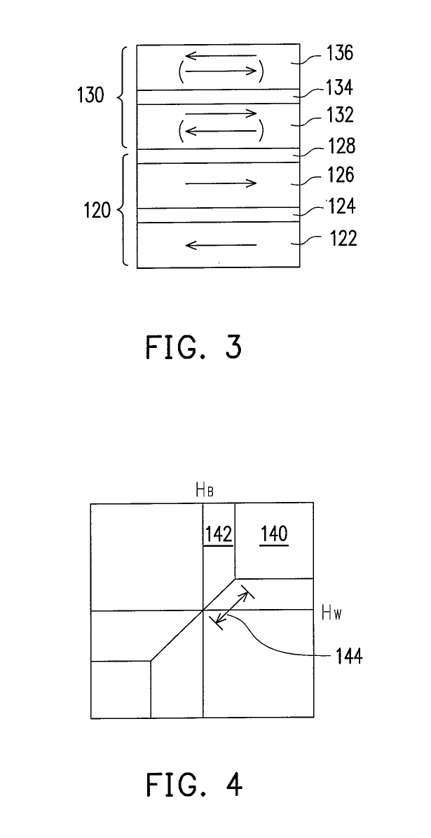

### DESCRIPTION OF EMBODIMENTS

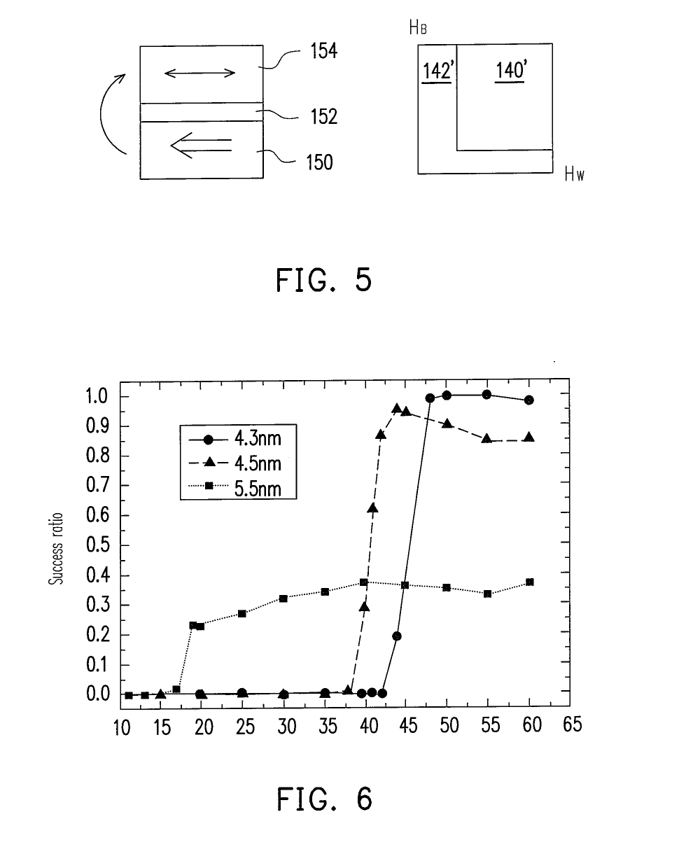

In the above conventional art, a bias field is applied to the free layer to make the toggle operation region near the origin, so as to lower the required write current. In the present invention, after the effect caused by the applied bias field has been further investigated, it is found that if the bias field is continuously added, the operation magnetic fields may become asymmetric in the operation region, as shown in FIG. 5. The operation magnetic field is generated by the operation current, such that the operation currents are asymmetric, and it is impossible to reduce the accessed operation current. FIG. 5 is a schematic view of the conventional mechanism of applying the bias field and the problem discussion according to the present invention. Referring to FIG. 5, for example, a pinned layer 150 has some net magnetic moments to generate the bias field to a free layer 154. The pinned layer 150 and the free layer 154 are isolated by a tunneling layer 152. When the bias field becomes large, as shown in the right drawing, a region 142′ indicates the non-operation region, and other regions belongs to a toggle operation region 140′. The toggle operation region 140′ moves towards the origin, and in addition, it makes the magnetic field H_{W} and the magnetic field H_{B} asymmetric, for example, in the region with lower write magnetic field, the magnetic field H_{W} is larger than the magnetic field H_{B}. In other words, when the value of the bias field is increased to exceed a certain value, the magnetization in the free layer cannot be normally operated, such that it is impossible to continuously reduce the write current. FIG. 6 is a schematic view of the effect of conventionally applying the bias field according to the present invention. Referring to FIG. 6, for example the thickness of the bottom pinned layer of the pinned layer 150 of FIG. 5 is increased to increase the total magnetic moment of the magnetization, so as to generate the bias field to the free layer. The larger the thickness is, the larger the generated total magnetic moment is.

The method can reduce the magnitude of the switching field, but a limited current may exist, if the bias field is continuously increased, the switching accuracy may be lowered. A curve of FIG. 6 is the simulated result under the bias field of different intensities. For the intensity of the bias field, it is maximal at the square points, smaller at the triangle points, and minimal at the round points. It can be found in FIG. 6 that when the bias field is continuously increased, the writing accuracy begins to reduce, and when the write magnetic field is within a range of 10 Oe to 60 Oe, the success ratio of the switching operation of the magnetization of the free layer is only at a degree of approximately 0.2-0.4, and no operable region exists. The conventional film layer structure condition cannot achieve write the data by using the conventional toggle magnetic field waveform.

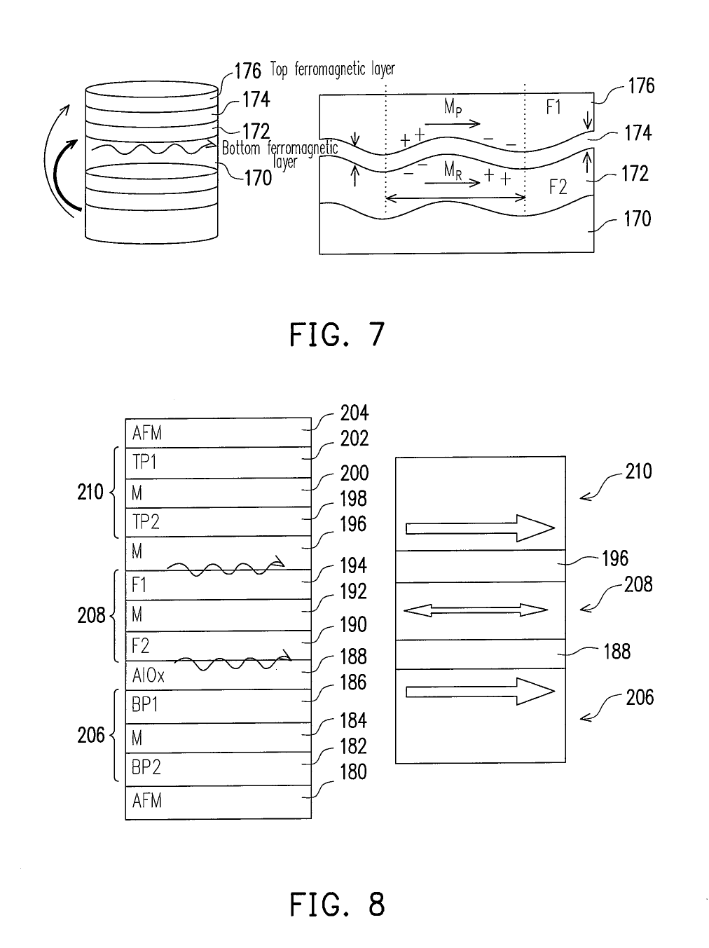

The present invention continues to discuss the reason of the above situation. FIG. 7 is a schematic view of discussing the mechanism of the bias field resulting in the operation failure according to the present invention. Referring to FIG. 7, a synthetic anti-ferromagnetic (SAF) layer is composed of a top ferromagnetic layer 176, a bottom ferromagnetic layer 172, and a middle coupling layer 174. The bottom ferromagnetic layer 172 and the pinned layer are isolated by an insulation layer 170. It is found from the result of the experiment and the result of micromagnetics simulation that the asymmetry of the operation regions may be resulted from the difference between the magnetic field sensed by the bottom ferromagnetic layer 172 and the bias field sensed by the top ferromagnetic layer 176 of the SAF layer. More particularly, the bottom ferromagnetic layer 172 in FIG. 7 is located on the insulation layer 170, senses a interference magnetic field generated by a rough surface of the interface, and it is called pinning field herein below. The top ferromagnetic layer 176 above the free layer does not sense the same pinning field, so the operation regions are asymmetric. It is not easy to use other externally applied magnetic field to counteract the pinning field generated by the rough surface. The method provided by the present invention is, for example, to establish a substantially symmetric structure, such that the pinning fields sensed by the top ferromagnetic layer 176 and the bottom ferromagnetic layer 172 in the SAF layer are nearly the same, so as to solve the topic that the operation regions are asymmetric.

FIG. 8 is a schematic sectional view of the structure of magnetic memory cell according to an embodiment of the present invention. Referring to FIG. 8, the structure of magnetic memory cell of one embodiment of the present invention includes an AFM layer 180 as a basic layer. A pinned layer 206 is formed over the AFM layer 180. A tunneling barrier layer 188 is formed over the pinned layer 206. A free layer 208 is formed over the tunneling barrier layer 188. A metal layer 196 is formed over the free layer 208. Another pinned layer 210 is formed over the metal layer 196. Another anti-ferromagnetic layer 204 is formed over the pinned layer 210. It is shown in the right drawing of FIG. 8 that the top pinned layer 210 and the bottom pinned layer 206 respectively generate the substantially same net magnetization, which apply substantially symmetrically desired bias fields to the free layer 208 from the top and the bottom of the free layer 208.

For the detailed structure and material, the magnetic memory cell is formed by magnetic multi-layer film. Generally, it is necessary to have a bottom electrode, a buffer layer (e.g. Ta), the AFM layer 180 (e.g. PtMn or MnIr), the pinned layer 206, for example a ferromagnetic pinned layer or a SAF pinned layer. For example, the pinned layer 206 is composed by a three-layer structure, which includes a bottom pinned layer 182, a coupling layer 184, and a top pinned layer 186, and the materials of the three-layer structure are, for example, CoFe/Ru/CoFe 182/184/186. The tunneling barrier layer 188 is, for example, AlOₓ or MgO, and the free layer 208 is, for example, the SAF free layer and is composed by, for example, two ferromagnetic layers 190 and 194 and a middle coupling layer 192, in which, the coupling layer 192 is, for example, a non-magnetic metal layer 192. The other pinned layer 210 is, for example, the ferromagnetic pinned layer or the SAF pinned layer. For example, the pinned layer 210 can be achieved by a three-layer structure including a bottom pinned layer 198, a coupling layer 200, and a top pinned layer 202. The other AFM layer 204 and the top electrode etc. are located above the pinned layer 210. In this embodiment, the suitable magnetic element can be SAF free layer. The two free layers are weakly coupled in anti-parallel, such that when the magnetic field draws near, they are mutually switched. For the manner of determining the data status, for example, the ferromagnetic layers located on two sides of the tunneling barrier layer (Al₂O₃ or MgO) are used to determine the data stored in the memory unit according to the parallel or the anti-parallel arrangement of the two ferromagnetic layers.

In an embodiment of the present invention, a magnetic easy axis of the AFM layer 204 is disposed parallel to the magnetic easy axis of the free layer 208. The ferromagnetic layer 190 and the ferromagnetic layer 194 substantially form a pair of anti-parallel magnetizations. In addition, the metal layer 196, for example, includes non-magnetic conductive metal material. The AFM layer 204 is of, for example, anti-ferromagnetic metal material.

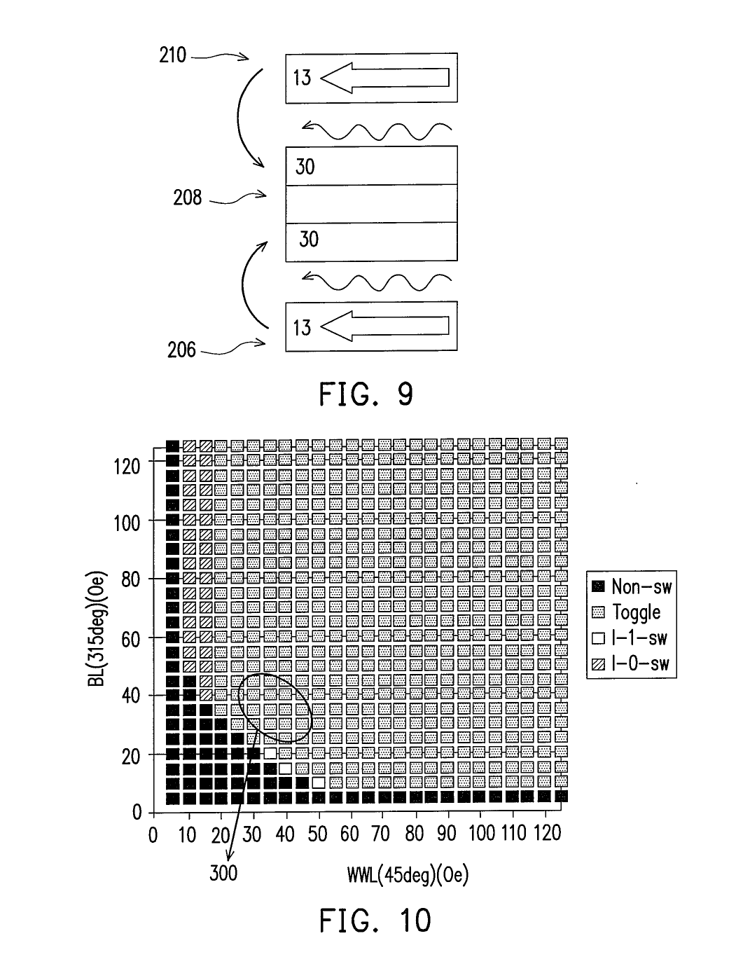

The structure provided by the above embodiment can make the top ferromagnetic layer 194 and the bottom ferromagnetic layer 190 in the free layer 208 sense the same magnetic field, so as to solve the problem generated in the conventional art. FIGS. 9-10 are schematic views of the structure and the simulated result according to an embodiment of the present invention. Referring to FIG. 9, the thickness of the top pinned layer 186 (referring to FIG. 8) of the pinned layer 206 and the bottom pinned layer 198 of the pinned layer 210 are, for example, 13 nm. The thickness of the top and the bottom ferromagnetic layers of the free layer 208 are, for example, 30 nm. Referring to FIG. 10, the point region belongs to the toggle mode operation region. It is found from the simulated result that the operation region 300 can be quite symmetric, and under the function of the strong bias field, the write magnetic field can be reduced to be quite low.

To sum up, in the present invention, the pinned layer above the free layer is increased to generate another bias field. The bias field lowers the operation magnetic field, in addition, because the effect of the pinning filed can be greatly eliminated, the operation region can be quite symmetric, thereby reducing the write current and modifying error probability during the data writing.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A structure of magnetic memory cell, comprising:
a first anti-ferromagnetic (AFM) layer;
a first pinned layer, formed over the first AFM layer;
a tunneling barrier layer, formed over the first pinned layer;
a free layer, formed over the tunneling barrier layer;
a metal layer, formed over the free layer;
a second pinned layer, formed over the metal layer; and
a second AFM layer, formed over the second pinned layer.

2. The structure of magnetic memory cell as claimed in claim 1, wherein a magnetic easy axis of the second AFM layer is disposed parallel to a magnetic easy axis of the free layer.

3. The structure of magnetic memory cell as claimed in claim 1, wherein the metal layer comprises non-magnetic conductive metal material.

4. The structure of magnetic memory cell as claimed in claim 1, wherein the second AFM layer comprises anti-ferromagnetic metal material.

5. The structure of magnetic memory cell as claimed in claim 1, wherein the first pinned layer comprises:
a first bottom pinned layer;
a first coupling layer; and
a first top pinned layer,
wherein the first coupling layer is located between the first bottom pinned layer and the first top pinned layer.

6. The structure of magnetic memory cell as claimed in claim 5, wherein the second pinned layer comprises:
a second bottom pinned layer;
a second coupling layer; and
a second top pinned layer,
wherein the second coupling layer is located between the second bottom pinned layer and the second top pinned layer.

7. The structure of magnetic memory cell as claimed in claim 1, wherein the second pinned layer comprises:
a second bottom pinned layer;
a second coupling layer; and
a second top pinned layer,
wherein the second coupling layer is located between the second bottom pinned layer and the second top pinned layer.

8. The structure of magnetic memory cell as claimed in claim 1, wherein the free layer comprises:
a first ferromagnetic layer, having a first magnetic easy axis;
a second ferromagnetic layer, having a second magnetic easy axis substantially parallel to the first magnetic easy axis; and
a coupling layer, located between the first ferromagnetic layer and the second ferromagnetic layer,
wherein the first ferromagnetic layer and the second ferromagnetic layer constitute a pair of substantially anti-parallel magnetizations.

9. The structure of magnetic memory cell as claimed in claim 1, wherein a plurality of magnetizations of the first pinned layer and the second pinned layer is parallel to a magnetic easy axis of the free layer.

10. The structure of magnetic memory cell as claimed in claim 1, wherein the first pinned layer and the second pinned layer respectively generate two fringe fields with the same direction applied to the free layer.

11. A magnetic memory device, comprising:
a memory array, composed of a plurality of magnetic memory cells, wherein each of the magnetic memory cells comprises:
a first anti-ferromagnetic (AFM) layer;
a first pinned layer, formed over the first AFM layer;
a tunneling barrier layer, formed over the first pinned layer;
a free layer, formed over the tunneling barrier layer;
a metal layer, formed over the free layer;
a second pinned layer, formed over the metal layer; and
a second AFM layer, formed over the second pinned layer.

12. The magnetic memory device as claimed in claim 11, wherein a magnetic easy axis of the second AFM layer is disposed parallel to a magnetic easy axis of the free layer.

13. The magnetic memory device as claimed in claim 11, wherein the metal layer comprises non-magnetic conductive metal material.

14. The magnetic memory device as claimed in claim 11, wherein the second AFM layer comprises anti-ferromagnetic metal material.

15. The magnetic memory device as claimed in claim 11, wherein the first pinned layer comprises:
a first bottom pinned layer;
a first coupling layer; and
a first top pinned layer,
wherein the first coupling layer is located between the first bottom pinned layer and the first top pinned layer.

16. The magnetic memory device as claimed in claim 15, wherein the second pinned layer comprises:
a second bottom pinned layer;
a second coupling layer; and
a second top pinned layer,
wherein the second coupling layer is located between the second bottom pinned layer and the second top pinned layer.

17. The magnetic memory device as claimed in claim 11, wherein the second pinned layer comprises:
a second bottom pinned layer;
a second coupling layer; and
a second top pinned layer,
wherein the second coupling layer is located between the second bottom pinned layer and the second top pinned layer.

18. The magnetic memory device as claimed in claim 11, wherein the free layer comprises:
a first ferromagnetic layer, having a first magnetic easy axis;
a second ferromagnetic layer, having a second magnetic easy axis substantially parallel to the first magnetic easy axis; and
a coupling layer, located between the first ferromagnetic layer and the second ferromagnetic layer,
wherein the first ferromagnetic layer and the second ferromagnetic layer constitute a pair of substantially anti-parallel magnetizations.

19. The magnetic memory device as claimed in claim 11, wherein a plurality of magnetizations of the first pinned layer and the second pinned layer is parallel to a magnetic easy axis of the free layer.

20. The magnetic memory device as claimed in claim 11, wherein the first pinned layer and the second pinned layer respectively generate two fringe fields with the same direction applied to the free layer.
